(19) United States
(12) Patent Application Publication
(10) Pub. No.: US 2025/0208175 A1
(43) Pub. Date: Jun. 26, 2025

(54) CURRENT SENSING CIRCUITS AND METHOD

(71) Applicant: STMicroelectronics International N.V., Geneva (CH)

(72) Inventor: Stephan WEBER, Bruckmuehl (DE)

(73) Assignee: STMicroelectronics International N.V., Geneva (CH)

(21) Appl. No.: 18/989,251

(22) Filed: Dec. 20, 2024

(30) Foreign Application Priority Data
Dec. 21, 2023 (IT) 102023000027660

(51) Int. Cl. G01R 19/00; H03F 3/45; H03K 17/60

(52) U.S. Cl. CPC G01R 19/0092; H03F 3/45179; H03K 17/60

(57) ABSTRACT

A first input node and a second input node are coupled to a sensing circuit element. A first transistor of a pair of differential transistors has a current flow path with a first transistor node coupled to the first input node to receive a current sensing signal and a second transistor node. A second transistor of the pair of differential transistors has a current flow path with a third transistor node coupled to the second input node to receive a current sensing signal and a fourth transistor node. An auxiliary amplifier circuit has a first auxiliary input node coupled to the second transistor node and a second auxiliary input node coupled to the fourth transistor node. An output node of the auxiliary amplifier circuit generates a control signal applied to a common control node of the pair of differential transistors.

### PRIORITY CLAIM

This application claims the priority benefit of Italian Application for Patent No. 102023000027660 filed on Dec. 21, 2023, the content of which is hereby incorporated by reference in its entirety to the maximum extent allowable by law.

### TECHNICAL FIELD

The description relates to circuits and methods for measurements of electric currents.

One or more embodiments may be applied to current sensing devices, preferably fast, accurate and compact current sensors.

### BACKGROUND

The possibility to measure a current flowing in a circuit branch is advantageous in many applications. A conventional measurement comprises measuring the voltage drop across a sense resistor via a readout amplifier with a low offset.

Existing current sensing arrangements are known, for instance, from the following references (each of which is incorporated herein by reference):
United States Patent Application Publication No. 2003/0020535 A1 (incorporated herein by reference) discloses a reference current/voltage generator insensitive to variations in power supply voltage and temperature. Temperature insensitivity is achieved by making the output current mirror a current that is the sum of two currents whose current paths have complementary temperature coefficients;
United States Patent Application Publication No. 2014/0362887 A1 (incorporated herein by reference) discloses a differential on-chip temperature sensor circuit which can be implemented in a standard complementary metal-oxide-semiconductor (CMOS) process using PNP transistors, and
U.S. Pat. No. 11,320,850 B1 (incorporated herein by reference) discloses a voltage selection circuit for selecting a voltage from a plurality of input voltages comprising a plurality of diodes, each diode having a first terminal coupled to one of the input voltages, and a current sensor configured to sense a current flow through each diode, wherein the selected voltage is dependent on the sensed current flow.

A known circuit architecture for current sensing is the feedback-based current sensor topology illustrated in FIG. 1, comprising a current sensor circuit 16 coupled to a sensing resistive element 16 interposed a power supply 12 (e.g., a battery) and a load circuit 14.

As exemplified in FIG. 1, the current sensor 16 comprises: an amplifier circuit 160 having a first input node 162 and a second input node 164 coupled to opposite ends of the sensing element (resistor) RS to detect an input voltage drop via a first input resistor R1 and a second input resistor R2, respectively; the amplifier circuit 160 is configured to provide an amplified voltage drop at an output node 166; a buffer Q0 (e.g., a BJT transistor) having a control (e.g., base or gate) node coupled to the output node 166 of the amplifier 160, having a first buffer node (e.g., collector node) coupled to an output resistive element R_{L} referred to ground GND, and having a second buffer node (e.g., emitter node) coupled to the first input node 162 of the amplifier 160 via a feedback branch 168; and an output node V_{OUT} at one end of the output resistive element R_{L} to provide a value of the voltage drop across, the output resistive element R_{L} having an electric current I_{L} flowing therethrough, the electric current being indicative of the current flowing in the sense resistor RS.

In a solution as exemplified in FIG. 1, the amplifier circuit 160 may comprise CMOS circuitry as it is exempt from errors in the beta factor. At the same time, CMOS devices may suffer from larger voltage mismatches than BJTs.

Chopping or auto-zeroing techniques may be used to reduce offset in CMOS solutions. At the same time, reducing an offset of the amplifier circuitry often comes at the expense of speed and area. Another drawback lies in the fact that is it challenging to find a satisfactory trade-off to fit wide input voltage ranges and reduced offset devices.

There is a need in the art to contribute in overcoming the aforementioned issues.

### SUMMARY

One or more embodiments may relate to a circuit.

One or more embodiments may relate to a corresponding current sensing device, such as a current sensor.

One or more embodiments may relate to a corresponding method.

One or more embodiments facilitate increasing speed and accuracy of current sensor amplifier circuits.

For instance, a solution as per the present disclosure facilitates providing fast and accurate current sensing circuits/devices suitable for a wide range of applications.

One or more embodiments may be equipped on a variety of system-on-chip, SoC, devices using current measurement arrangements.

One or more embodiments present one or more of the following advantages: support operation with a wider range of common-mode voltage values than existing solution; facilitate achieving reasonable high speed and very high accuracy combined with low area; and facilitate cost reduction and simplify manufacturing.

In an embodiment, a circuit comprises: a first input node and a second input node configured to be coupled at the terminals of a sensing circuit element to receive a current sensing signal therefrom; a pair of transistors having first transistor nodes coupled to the first and the second input nodes of the circuit to receive the current sensing signal therefrom and configured to provide an amplified current sensing signal at an output node via an output stage; wherein the pair of transistors comprises a first transistor having a current flow path therethrough via a first transistor node coupled to the first input node and a second transistor node coupled to a first biasing current generator circuit, and a second transistor having a current flow path therethrough via a third transistor nodes coupled to the second input node and a fourth transistor node coupled to a second biasing current generator circuit, the first and second transistors in the pair of transistors having a common control node; and an auxiliary amplifier circuit having a first auxiliary input node coupled to the second transistor node of the first transistor and a second auxiliary input node coupled to the fourth transistor node of the second transistor, the auxiliary amplifier circuit further having an output node coupled to the common control node of the pair of transistors.

### BRIEF DESCRIPTION OF THE DRAWINGS

One or more embodiments will now be described, by way of non-limiting example only, with reference to the annexed Figures, wherein:

FIG. 1 shows a known circuit architecture for current sensing;

FIG. 2 is a circuit diagram exemplary of an amplifier circuit;

FIG. 3 is a circuit diagram exemplary of an amplifier circuit;

FIG. 4 is a circuit diagram exemplary of a further amplifier circuit;

FIG. 5 is a diagram exemplary of principles underlying one or more embodiments;

FIG. 6 is a diagram exemplary of principles underlying one or more embodiments;

FIG. 7 is a circuit diagram exemplary of a portion of the circuit exemplified in FIG. 3; and

FIG. 8 is a circuit diagram exemplary of a portion of the amplifier circuit of FIG. 4.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale. The edges of features drawn in the figures do not necessarily indicate the termination of the extent of the feature.

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The references used herein are provided merely for convenience and hence do not define the extent of protection or the scope of the embodiments.

For the sake of simplicity, in the following detailed description a same reference symbol may be used to designate both a node/line in a circuit and a signal which may occur at that node or line.

Unless stated otherwise, like reference symbols used in the following throughout the figures represent like elements. Therefore, a repetition of their description may not be repeated each and every time for the sake of brevity.

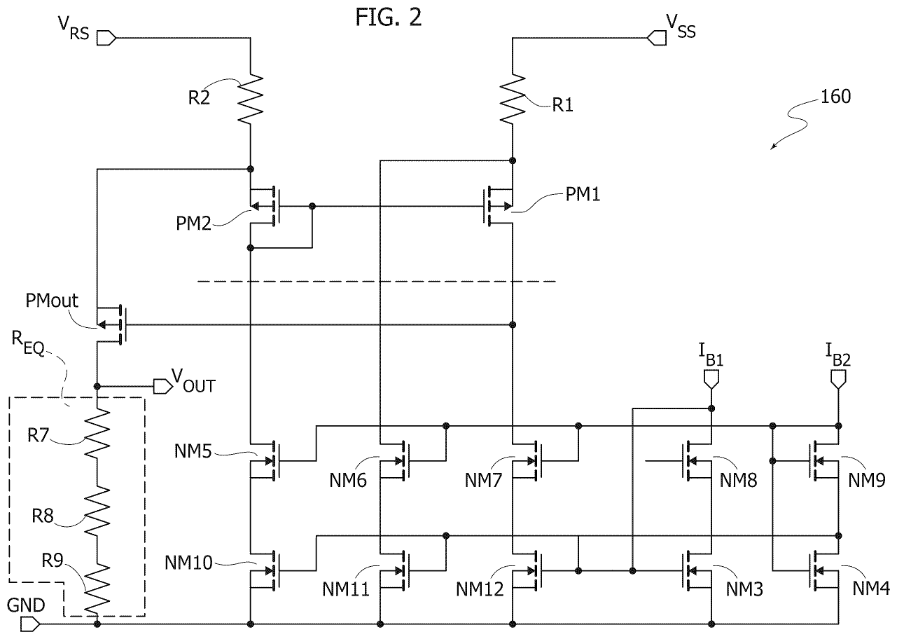

As exemplified in FIG. 2, a known CMOS implementation of an amplifier circuit architecture 160 comprises: a current mirror arrangement of transistors PM1, PM2 (e.g., p-channel MOS transistor); a further transistor PM_{OUT} in a buffer arrangement coupled to the current mirror PM1, PM2; a series of resistive elements R7, R8, R9 (or an equivalent resistive element R_{EQ}) interposed the further transistor PM_{OUT} and ground GND; a first cascode pair NM5, NM10 arranged on a same current line of the transistor PM2 of the current mirror arrangement PM1, PM2; a second cascode pair NM6, NM11 coupled to the transistor PM1 of the current mirror arrangement PM1, PM2; and biasing circuitry NM7, NM8, NM9, NM12, NM13, NM14 configured to provide biasing current I_{B1}, I_{B2} to the cascode pairs NM5, NM6, NM10, NM11.

In order to perform signal amplification, cascode transistors NM5, NM6, NM10, NM12 preferably comprise “high voltage” transistors.

Preferably, the transistor NM6 is configured to add (little) offset current into the first resistor R1 for operation at zero input current.

The circuit 160 exemplified in FIG. 2 can be operated in a range of input voltage values down to 2.7 Volts while showing some performance reduction due to mismatch issues. Therefore, the circuit 160 is hardly suitable for applications in which the input voltage ranges in a wide range of common-mode values, e.g., 2.7 Volts to 24 Volts at the input nodes VRS, VSS of the amplifier 160.

Moreover, the circuit 160 has a limited accuracy. There is an interest in improving on accuracy while maintaining at least similar voltage capabilities.

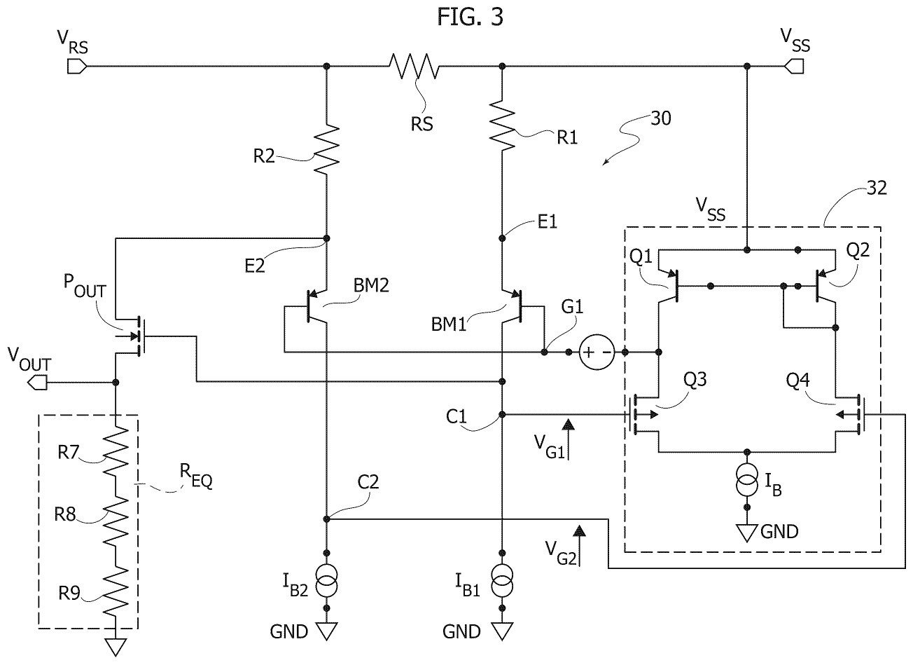

The Inventor has observed that introducing an auxiliary amplification circuit facilitates providing an improved amplifier circuit. As exemplified in FIGS. 3 to 8, such an improved amplifier circuit 30 is still suitable for wide ranges of common mode values of the input voltage drop across input nodes VSS, VRS, but with improved accuracy.

As exemplified in FIG. 3, amplifier circuit 30 comprises: a (e.g, differential) pair of (e.g., pnp BJT) transistors BM1, BM2 coupled to the input resistive elements R1, R2 and to biasing current generator circuits I_{B1}, I_{B2}; an output transistor P_{OUT} coupled to the pair of transistors BM1, BM2; a series of resistive elements R7, R8, R9 (or the equivalent resistive element R_{EQ}) interposed the output transistor P_{OUT} and ground GND; and an (new, additional) auxiliary amplifier circuit 32 coupled to a common control node (e.g., base) G1 of transistors in the pair of transistors BM1, BM2, for instance to compensate beta errors by driving the base rail G1 of the pair of transistors.

As exemplified in FIG. 3, the pair of transistors BM1, BM2 comprises: a first (e.g., pnp BJT) transistor BM1 having a first current flow channel therethrough between a first (e.g., emitter) transistor terminal E1 coupled to the first input resistance R1 and a second (e.g., collector) transistor terminal C1 coupled to a first bias current generator I_{B1}; and a second (e.g., pnp BJT) transistor BM2 having a second current flow channel therethrough between a third (e.g., emitter) transistor terminal E2 coupled to the second input resistance R2 and a fourth (e.g., collector) transistor terminal C2 coupled to a second bias current generator I_{B2}.

As exemplified in FIG. 3, the auxiliary amplifier circuit 32 facilitates ensuring that a voltage drop V_{CE} across terminals of the transistors in the pair of transistors BM1, BM2 remains substantially the same. For instance, this is the consequence of coupling input nodes of the auxiliary amplifier circuit 32 to the second transistor terminal C1 of the first transistor BM1 and to the fourth transistor terminal C2 of the second transistor BM1. As a result, the early voltage errors of the pnp BJT transistors employed in the differential BM1, BM2 couple may be countered or compensated.

As exemplified in FIG. 3, the auxiliary amplifier circuit 32 (such as an operational amplifier, for instance) comprises: a current mirror arrangement Q1, Q2 comprising a first (e.g., pnp BJT) current mirror transistor Q1 and a second current mirror transistor Q2 having a common control node therebetween and a common terminal coupled to the supply voltage VSS; and an auxiliary differential arrangement of (e.g., n-channel MOS) transistors Q3, Q4 having a first input node coupled to the second transistor terminal C1 and a second input node coupled to the fourth transistor terminal C2 of the transistor pair BM1, BM2, the auxiliary differential pair Q3, Q4 having a common node coupled to a biasing current generator circuit I_{B} referred to ground GND.

As mentioned, the use of the auxiliary amplifier circuit 32 facilitates maintaining a same voltage level (e.g., VG1=VG2) at the control nodes G1 (e.g., bases) of the pair of transistors BM1, BM2, thereby reducing amplification issues deriving from (e.g., beta) parameter mismatches.

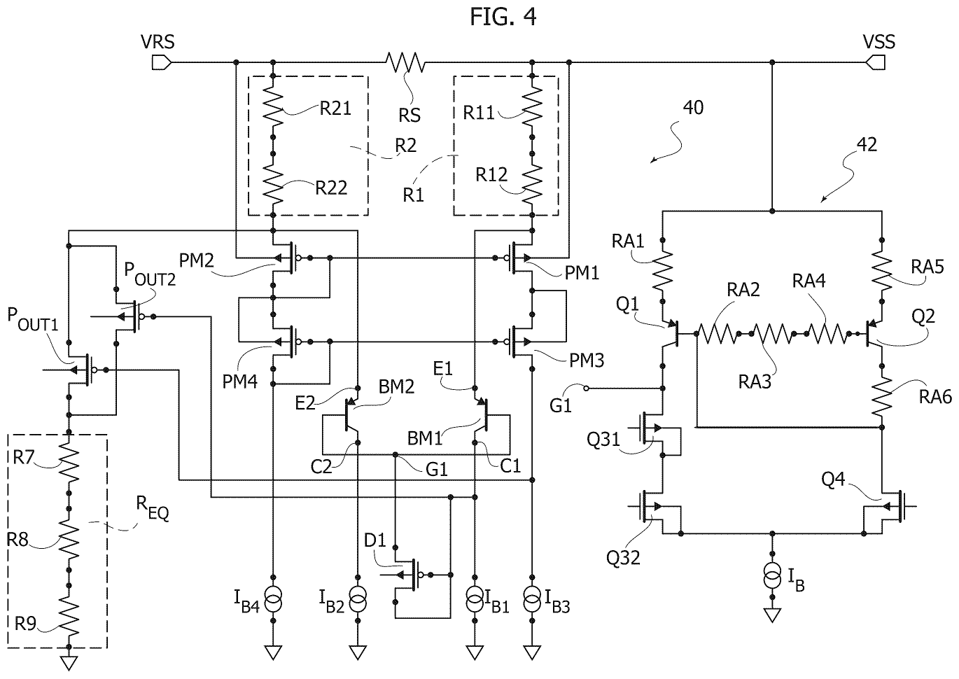

The circuit architecture 30 exemplified in FIG. 3 may present multiple stable operating points. It may be possible to select an operating point out of the multiple ones available for circuit 30 exemplified in FIG. 3 by coupling the architecture to startup circuitry 40, 40′, as exemplified in FIGS. 4 to 8.

As exemplified in FIG. 4, the startup circuitry 40 comprises: a current mirror arrangement of transistors PM1, PM2 (e.g., p-channel MOS transistor) coupled to the differential couple of BJT transistors BM1, BM2; optionally, a (e.g., cascode) arrangement of transistors PM3 and PM4 coupled to the current mirror arrangement of transistors PM1, PM2; and a mirror arrangement of (e.g., p-channel MOS) transistors I_{B3}, I_{B4} in parallel (in particular, transistors having no multiple op-points) and a minimum selector circuit comprising transistors Q31, Q32 arranged in series with (e.g., n-channel MOS) transistors Q3A, Q4A at the input nodes of auxiliary amplifier 42.

As exemplified in FIG. 4, a diode (e.g., body diode of a MOS transistor) D1 is coupled to the common (e.g., base) control node G1 of the input pair of transistors BM1, BM2, thereby forming a clamp to limit voltage excursions at the control node G1.

As exemplified in FIG. 4, in order to increase accuracy, the auxiliary amplifier circuit 42 further comprises resistive elements RA1, RA2, RA3, RA4, RA5, RA6 coupled to the current mirror arrangement Q1, Q2.

For instance, a resistive element RA6 can be coupled intermediate a control node of a first current mirror transistor Q1 and a current node of a second current mirror transistor Q2, thereby implementing a beta compensation technique.

As exemplified in FIG. 4, the circuit 40 comprises a first series of resistive elements R11, R12 having an equivalent resistance to that of the first resistive element R1 and/or a second series of resistive elements R21, R22 having an equivalent resistance to that of the second resistive element R2.

In variant embodiments, other extensions (like for instance, a cascode) may also be employed in the startup circuitry 40 of the auxiliary amplifier 42.

As exemplified in FIG. 4, two output p-channel MOS transistors P_{OUT1}, P_{OUT2} having a drain-source channel path in parallel and different gate voltages may be employed in an exemplary scenario as an output stage.

As exemplified in FIG. 7, a minimum current selector Q31, Q32 may be employed in the startup circuitry 42 of the auxiliary amplifier 32. For instance, the minimum current selector Q31, Q32 comprises a first (e.g., n-channel MOS) transistors Q31 in series with a second (e.g., n-channel MOS) transistor Q32. For instance, if the gate of the first MOS Q31 reaches a relatively high voltage, it saturates thereby acting like a closed switch. Therefore, in such an exemplary scenario the behavior of the minimum selector circuit Q31, Q32 is dominated by the second transistor Q32: as a result, the differential couple of the auxiliary amplifier 32 is formed by transistors Q32 and Q4.

In another complementary scenario, if the gate of the second transistor Q32 reaches a voltage higher than that of the first transistor Q31, saturating as a result, the circuit Q31, Q32 is dominated by the first transistor Q31 that forms the differential couple of the auxiliary amplifier 32 together with transistor Q4.

As exemplified in FIG. 7, the minimum selector circuit Q31, Q32 may be modeled as a single (e.g., n-channel MOS) transistor Q3A which reacts to the minimum gate voltage.

Thanks to the employ of the minimum selection circuit Q31, Q32, in the normal operating condition, after startup, the MOS startup circuit 40 becomes (substantially) inactive (as it may still be operating but at a very low level of bias current, thereby negligibly affecting signal amplification) and is not influencing the normal BJT-based operation.

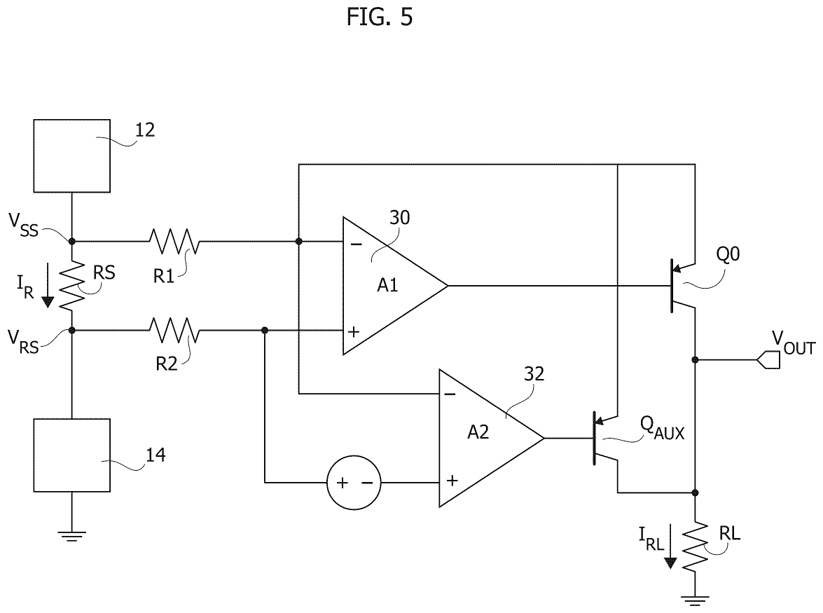

FIG. 5 is exemplary of principles underlying one or more embodiments.

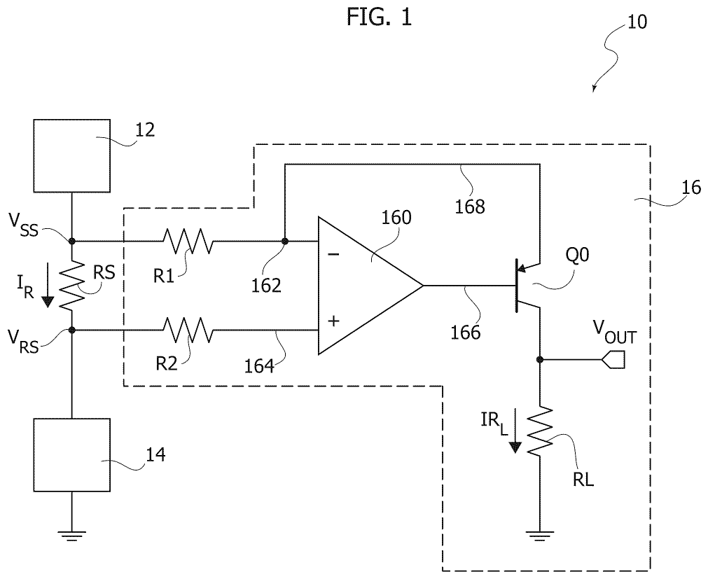

In the prior-art case exemplified in FIG. 1, in case the amplifier 30 is inactive, that is in case it has an output voltage V_{OUT} close to the positive supply voltage, it follows that a current flowing through transistor Q0 is zero and the output voltage V_{OUT} is also zero.

As exemplified in FIG. 5, when a second auxiliary amplifier 32 comprising MOS transistors (and considering absent the startup issue for the sake of simplicity) is coupled in parallel to the amplifier circuit 30, the auxiliary amplifier 32 may become dominant.

Therefore, a method of operating the amplifier 30 comprises turning off the auxiliary amplifier 32 (after the startup phase), for instance by providing a small input offset voltage to the auxiliary amplifier 32, 42.

For instance, once provided the offset (with the adequate polarity) results in the auxiliary amplifier 32, 42 increasing an output voltage V_{OUT}, which in turn results in a reduced current in the (e.g., pnp BJT) transistors BM1, BM2, thereby reducing the respective contribution to the output voltage V_{OUT}. Such a reduced contribution to the output voltage V_{OUT} may reduce the contribution of the auxiliary amplifier 32 to output voltage V_{OUT}, thereby maintaining the more accurate (e.g., BJT-based) amplifier 30 as most significant to define the overall amplification accuracy.

As exemplified herein, the offset may be relatively small in comparison to the gain of both amplifier circuits 30, 32 as the latter can be rather large (e.g., gain greater than 1000).

It is noted that while Q0 and Q_{AUX} are represented as BJT transistors in FIG. 5, this implementation is purely exemplary and in no way limiting as in one or more embodiments (e.g., p-channel) MOS transistors may be used or notionally any other kind of transistor.

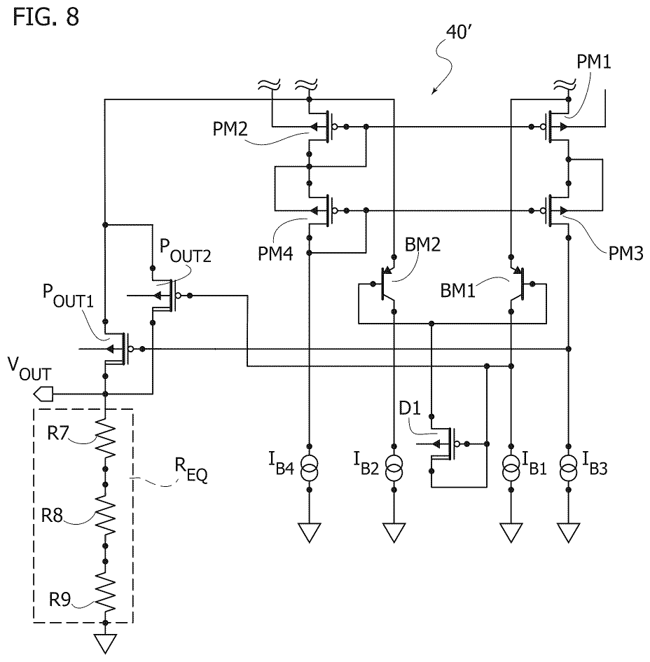

As exemplified in FIG. 8 that shows a portion 40′ of the startup circuitry 40 exemplified in FIG. 4, the BJT part BM1, BM2 and the MOS part PM1, PM2 of the current mirror arrangement work in parallel. Therefore, the CMOS part (e.g., PM1, PM2, P_{OUT}) may impact the overall accuracy. In order to counter this effect, current mirror transistors PM3, PM4 may be designed to show a small offset in multiplication factors (e.g., m=9 and m=10).

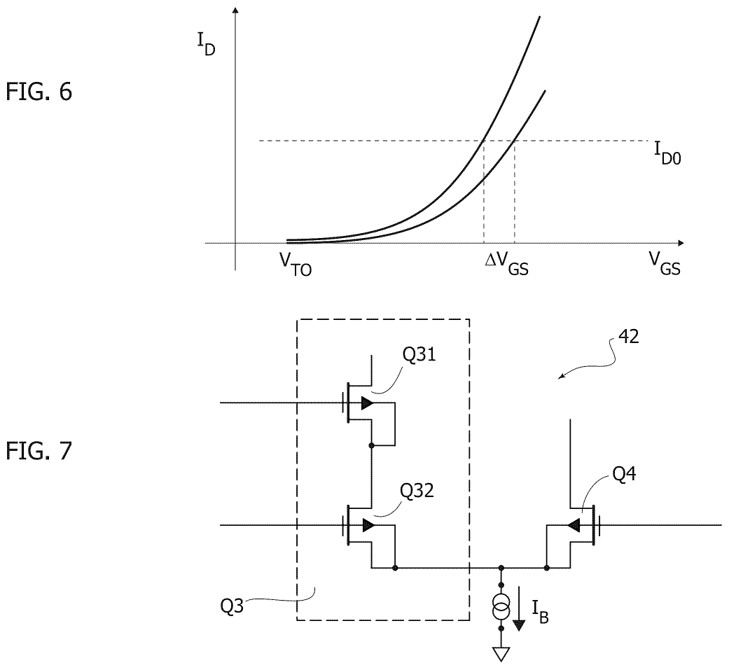

As exemplified in FIG. 6, for a given current value I_{D0} of the drain current (represented in ordinate axis of the plot of FIG. 6) the gate-source voltage V_{GS} (represented in abscissa axis of the plot of FIG. 6) of a MOS transistor depends on the size (in terms of width W and length L) of the transistor. For a same length L, a larger width W leads to a lower current density and to a lower gate-source voltage drop VGS. Using small unit devices and multiples of a common unit facilitates to control more precisely the variation of gate-source voltage. As exemplified in FIG. 6, a difference ΔV_{GS} about few mV may be obtained by varying the multiplication factor from m=9 to m=10, for a given current value I_{DO}.

Going back to FIG. 8, as a result of the slightly different multiplication factors, in operation only the BJT arrangement BM1, BM2 is actively driving the corresponding PMOS output transistors PM1, PM2. In this way, the accuracy is increased as it is dominated by the (e.g., pnp BJT) pair of transistors BM1, BM2, whereas the less accurate MOS transistors have a substantially negligible impact thereupon.

As exemplified in FIGS. 3 to 8, a circuit 30 comprises: a first input node VSS and a second input node VRS configured to be coupled at the terminals of a sensing circuit element R_{S} to receive a current sensing signal I_{R} therefrom; and a pair of (e.g., differential) transistors BM1, BM2 having first transistor nodes E1, E2 coupled to the first VSS and second VRS input nodes of the circuit to receive the current sensing signal therefrom and configured to provide an amplified current sensing signal at an output node V_{OUT} via an output stage P_{OUT}, R_{EQ}.

For instance, the pair of transistors comprises a first transistor BM1 having a current flow path therethrough via a first transistor node E1 coupled to the first input node and a second transistor node C1 coupled to a first biasing current generator circuit I_{B1}, the pair of transistors further comprising a second transistor BM2 having a current flow path therethrough via a third transistor nodes E2) coupled to the second input node and a fourth transistor node C2 coupled to a second biasing current generator circuit I_{B2}, the first and second transistors in the pair of transistors (BM1, BM2) having a common control node (G1); and an auxiliary amplifier circuit 32 having a first auxiliary input node coupled to the second transistor node of the first transistor and a second auxiliary input node coupled to the fourth transistor node of the second transistor, the auxiliary amplifier circuit further having an output node coupled to the common control node G1 of the pair of transistors.

As exemplified in FIGS. 3 to 8, the auxiliary amplifier circuit comprises: an auxiliary differential arrangement of transistors Q3; Q31, Q32, Q4 comprising transistors having a common biasing node coupled to a biasing current generator I_{B} referred to ground GND; and an auxiliary current mirror arrangement of transistors Q1, Q2 coupled to the first input node and to the auxiliary differential arrangement of transistors.

As exemplified in FIGS. 3 to 8, the output stage P_{OUT}, R_{EQ} comprises: a further arrangement of transistors P_{OUT}; P_{OUT}1, P_{OUT}2 coupled to the pair of transistors; and a set of resistive elements R7, R8, R9 interposed the further arrangement of transistors and ground.

As exemplified herein, the pair of transistors comprises bipolar junction transistors, BJT, preferably pnp BJT.

As exemplified herein, the circuit comprises: a minimum selector circuit Q31, Q32 coupled to the auxiliary amplifier circuit; and/or a diode D1 coupled to the common control node of the pair of transistors.

As exemplified herein, the circuit comprises a current mirror arrangement of transistors PM1, PM2 configured to mirror the current sensing signal. For instance, the current mirror arrangement of transistors PM1, PM2 comprises a first current mirror transistor PM1 coupled to the first input node and a second current mirror transistor PM2 coupled to the second input node VRS, the first current mirror transistor and the second current mirror transistor having a common control node.

As exemplified herein, a further current mirror arrangement of transistors PM3, PM4 is coupled to the current mirror arrangement of transistors. For instance, the transistors in the further current mirror arrangement of transistors PM3, PM4 have different multiplication factor value in order to introduce an offset current to turn off the auxiliary amplifier circuit.

As exemplified in FIGS. 1 to 8, a current sensing device comprises: a power supply 12 configured to supply an electrical current; a load circuit 14 coupled to the power supply to receive the electrical current therefrom; a sensing circuit element R_{S} interposed the power supply and the load circuit and having a current flow therethrough indicative of a current flowing in said load circuit; and a circuit 30 according to any one of the previous claims coupled to the sensing circuit element to receive the current sensing signal therefrom and to provide an amplified current sensing signal at an output node V_{OUT}.

As exemplified herein, a method comprises: coupling the first input node VSS and the second input node VRS of a circuit 30 according to the present disclosure to the terminals of a sensing circuit element R_{S} and receiving a current sensing signal I_{R} from said sensing circuit element; applying signal amplification processing to said current sensing signal via a pair of transistors BM1, BM2 having input nodes E1, E2 coupled to the first and second input nodes of the circuit to receive the current sensing signal therefrom and configured to provide an amplified current sensing signal at an output node V_{OUT} via an output stage P_{OUT}, R_{EQ} of the circuit; and coupling a first auxiliary input node of an auxiliary amplifier circuit 32 to the second transistor node C1 of the first transistor and coupling a second auxiliary input node of the auxiliary amplification circuit to the fourth transistor node C2 of the second transistor, the auxiliary amplifier circuit further having an output node coupled to the common control node G1 of the pair of transistors.

As exemplified herein, the circuit 30 preferably further comprises over-voltage protection circuitry (not visible in FIGS. 3-4), such as Zener diodes, for instance.

One or more embodiments have been discussed mainly with reference to the current sensing application for the sake of simplicity, being otherwise understood that the solution as per the present disclosure may be equipped, at least notionally, on any signal amplification circuit solution irrespective of the application.

For instance, temperature sensors may be exemplary of electronic devices that may be equipped with the solution as per the present disclosure.

In one or more embodiments the startup circuitry 40 may be implemented in other ways, such as employing bandgap reference circuitry.

It will be otherwise understood that the various individual implementing options exemplified throughout the figures accompanying this description are not necessarily intended to be adopted in the same combinations exemplified in the figures. One or more embodiments may thus adopt these (otherwise non-mandatory) options individually and/or in different combinations with respect to the combination exemplified in the accompanying figures.

The claims are an integral part of the technical teaching provided herein with reference to the embodiments.

Without prejudice to the underlying principles, the details and embodiments may vary, even significantly, with respect to what has been described by way of example only, without departing from the extent of protection. The extent of protection is defined by the annexed claims.

1. A circuit, comprising:
a first input node and a second input node configured to receive current sensing signals from terminals of a sensing circuit element;
a pair of transistors coupled to the first and the second input nodes and configured to provide an amplified current sensing signal at an output node via an output stage;
wherein the pair of transistors comprises a first transistor having a current flow path therethrough via a first transistor node coupled to the first input node and a second transistor node coupled to a first biasing current generator circuit, and a second transistor having a current flow path therethrough via a third transistor node coupled to the second input node and a fourth transistor node coupled to a second biasing current generator circuit, the first and second transistors in the pair of transistors having a common control node; and
an auxiliary amplifier circuit having a first auxiliary input node coupled to the second transistor node of the first transistor and a second auxiliary input node coupled to the fourth transistor node of the second transistor, the auxiliary amplifier circuit further having an output node generating a control signal applied to the common control node of the pair of transistors.

2. The circuit of claim 1, wherein the auxiliary amplifier circuit comprises:
an auxiliary differential arrangement of transistors comprising transistors having a common biasing node coupled to a biasing current generator referred to ground; and
an auxiliary current mirror arrangement of transistors coupled to the first input node and to the auxiliary differential arrangement of transistors.

3. The circuit of claim 1, wherein said output stage comprises:
a further arrangement of transistors coupled to the pair of transistors; and
a set of resistive elements interposed between the further arrangement of transistors and ground.

4. The circuit of claim 1, wherein said pair of transistors comprises bipolar junction transistors (BJT).

5. The circuit of claim 1, comprising a minimum selector circuit coupled to the auxiliary amplifier circuit.

6. The circuit of claim, comprising a diode coupled to the common control node of the pair of transistors of the circuit.

7. The circuit of claim 1, comprising:
a current mirror arrangement of transistors configured to mirror said current sensing signal;
wherein the current mirror arrangement of transistors comprises a first current mirror transistor coupled to the first input node and a second current mirror transistor coupled to the second input node, the first current mirror transistor and the second current mirror transistor having a common control node.

8. The circuit of claim 7, comprising a further current mirror arrangement of transistors coupled in series with the current mirror arrangement of transistors.

9. The circuit of claim 8, wherein the transistors in the further current mirror arrangement of transistors have a different multiplication factor value in order to introduce an offset current to turn off the auxiliary amplifier circuit.

10. The circuit of claim 8, wherein the output stage comprises:
a first output transistor having a control node coupled to receive a first control signal generated by an output from said pair of transistors;
a second output transistor having a control node coupled to receive a second control signal generated by an output from said further current mirror arrangement of transistors;
wherein the first and second output transistors are connected in parallel.

11. The circuit of claim 10, further comprising a clamping diode connected between the output from said further current mirror arrangement of transistors and the common control node of the pair of transistors.

12. A current sensing device, comprising:
a power supply configured to supply an electrical current;
a load circuit coupled to the power supply to receive the electrical current therefrom;
a sensing circuit element interposed the power supply and the load circuit and having a current flow therethrough indicative of a current flowing in said load circuit, and
the circuit of claim 1 coupled to the sensing circuit element to receive the current sensing signal therefrom and to provide an amplified current sensing signal at the output node.

13. A method, comprising:
receiving current sensing signals from terminals of a sensing circuit element;
applying signal amplification processing to said current sensing signals via a pair of transistors having first conduction nodes coupled to the terminals of a sensing circuit element;
generating an amplified current sensing signal at an output node via an output stage;
differentially amplifying signals at second conduction nodes of the pair of transistors to generate a control signal; and
applying the control signal to common control nodes of the pair of transistors.
